(19) United States
(12) Patent Application Publication
(10) Pub. No.: US 2007/0072445 A1
(43) Pub. Date: Mar. 29, 2007

(54) Flat image detector for recording digital x-ray images

(76) Inventor: Martin Spahn, Chicago, IL (US)

Correspondence Address: HARNESS, DICKEY & PIERCE, P.L.C., P.O.BOX 8910, RESTON, VA, 20195, US

(21) Appl. No.: 11/525,907

(22) Filed: Sep. 25, 2006

(30) Foreign Application Priority Data
Sep. 26, 2005 (DE) 10 2005 045 901.3

(51) Int. Cl. H05K 1/00

(52) U.S. Cl. 439/65

(57) ABSTRACT

In order to improve mechanical stability against impact and permit a high degree of bending, a flat image detector is disclosed for recording digital x-ray images. The detector includes a converter layer, and an active pixel matrix made from pixel readout units and an electronics printed circuit board. The electronics printed circuit board is subdivided into at least two printed circuit board modules. The respective base surface of the printed circuit board modules is substantially smaller than the base surface of the electronics printed circuit board.

### PRIORITY STATEMENT

The present application hereby claims priority under 35 U.S.C. §119 on German patent application number DE 10 2005 045 901.3 filed Sep. 26, 2005, the entire contents of which is hereby incorporated herein by reference.

### FIELD

The invention generally relates to a flat image detector for recording digital x-ray images.

### BACKGROUND

Flat image detectors have been applied for some years now in digital x-ray imaging. Such detectors are based on an active readout matrix for example made from amorphous silicon (a-Si) with a direct converter layer coating or a scintillator layer coating in front of it. The incident x-radiation is converted into electric charge directly in the direct converter layer or indirectly via light generation in the scintillator layer. The readout matrix, which is generally arranged on a glass substrate and subdivided into a multiplicity of pixel readout units, stores the electric charge in a spatially resolved fashion. Reference may also be made as regards the technical background of a flat image detector to M. Spahn et al., “Flachbilddetektoren in der Röntgendiagnostik”, [“Flat image detectors in x-ray diagnostics”], Der Radiologe 43 (2003), pages 340 to 350.

Also known in this context are portable flat image detectors that can be used in a mobile fashion and can be connected to any desired x-ray systems for the purpose of data transmission and power supply by means of a wired or wireless connection. It is particularly important for such portable flat image detectors to have as low a weight as possible, a format that exceeds the format of the active surface as little as possible, and as slight a thickness as possible. However, the latter conditions lead to an increased sensitivity to impact, breakage and shock. The so called electronics board, also termed electronics printed circuit board, is especially extremely sensitive to bending or twisting, since supply leads arranged on the electronics printed circuit board (multi-layer PCBs) or other electronics components can easily break.

### SUMMARY

In at least one embodiment of the invention, a flat image detector is provided that, in conjunction with small dimensions and low weight, has a mechanical stability that is as high as possible, for example against impact and bending.

Because the base surfaces of the printed circuit board modules are substantially smaller than the base surface of the electronics printed circuit board, in the case of the flat image detector according to at least one embodiment of the invention having an electronics printed circuit board subdivided into at least two printed circuit board modules, the bending radii of the individual printed circuit board modules are substantially smaller than the bending radius of the individual electronics printed circuit board, which is larger in terms of area, such that breakages in the supply leads or damage to the electronics components come about substantially less frequently in the event of shocks and bending even without enlargement of the outer dimensions or the weight of the flat image detector. Moreover, the use of printed circuit board modules enables damaged electronics components to be exchanged more simply, more cost effectively and at less expense.

At least two printed circuit board modules are interconnected via flexible lines in a way that is advantageous for additional flexibility and particularly high stability of the electronics printed circuit board of the flat image detector.

According to one refinement of at least one embodiment of the invention, the various printed circuit board modules are respectively assigned various specific functions. An easy division into logic units is thereby possible, and an exchange of components or printed circuit board modules, for example for maintenance purposes, is facilitated.

According to further refinements of at least one embodiment of the invention, a first printed circuit board module forms an analog electronics unit, a second printed circuit board module forms a digital electronics unit, a further printed circuit board module forms a communications electronics unit, and yet a further printed circuit board module forms a drive and readout electronics unit.

A particularly advantageous possible use for at least one embodiment of the invention is given by a mobile, in particular wireless, flat image detector, since the risk of the flat image detector falling down or impacting is particularly frequent here.

### BRIEF DESCRIPTION OF THE DRAWINGS

The invention as well as further advantageous refinements are explained in more detail below in the drawings with the aid of schematically illustrated example embodiments without thereby restricting the invention to these example embodiments; in the drawings:

FIG. 1 shows a lateral section through a flat image detector according to the prior art;

FIG. 2 shows a lateral section through a flat image detector according to an embodiment of the invention having an electronics printed circuit board subdivided into printed circuit board modules

FIG. 3 shows a plan view of a section through a further flat image detector according to an embodiment of the invention having an electronics printed circuit board that is subdivided into printed circuit board modules and respectively has various functions.

### DETAILED DESCRIPTION OF THE EXAMPLE EMBODIMENTS

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

In describing example embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner.

Referencing the drawings, wherein like reference numerals designate identical or corresponding parts throughout the several views, example embodiments of the present patent application are hereafter described.

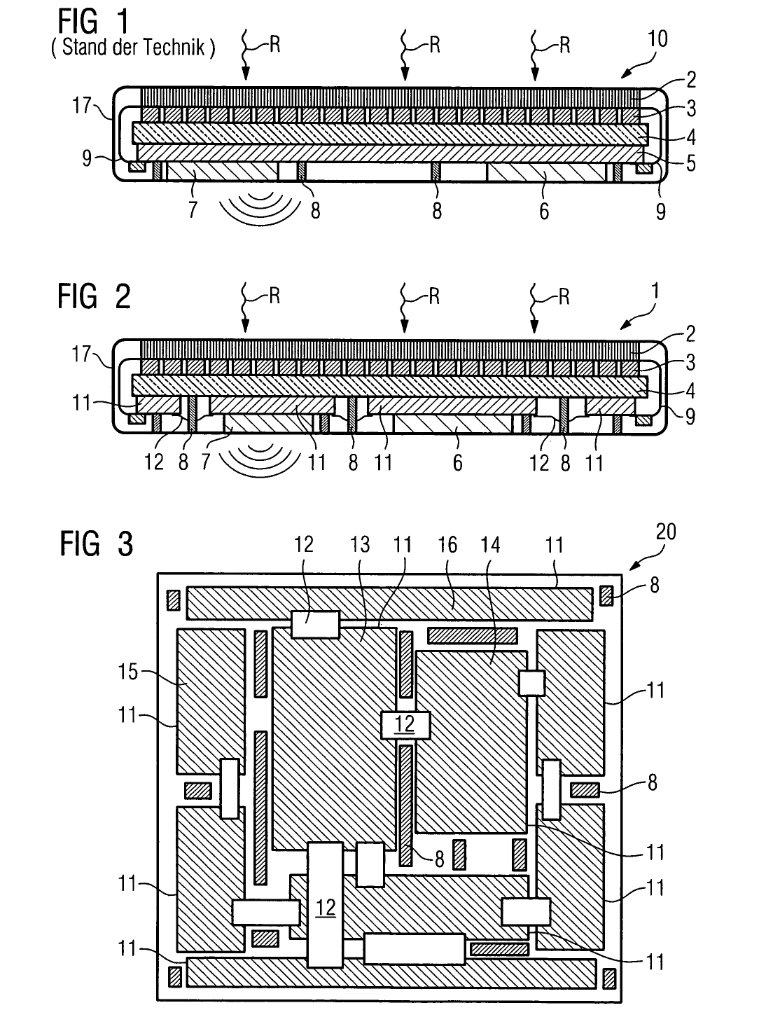

FIG. 1 shows a flat image detector 10 according to the prior art that is spanned by a housing 17 and has a unipartite electronics printed circuit board 5 extending over substantially the entire surface of the flat image detector 10. Moreover, the flat image detector 10 has a scintillator layer 2 for converting an x-radiation R into light, an active matrix 3, arranged on a glass substrate 4 and made from pixel readout units, an accumulator 6 and a wireless data transmission unit 7.

Here, the entire electronics of all the individual components are arranged on the electronics printed circuit board 5, for example an analog electronics unit, a digital electronics unit and a communications electronics unit are located thereon. For this reason, the remaining components of the flat image detector 10 are connected to the electronics printed circuit board 5 via connecting lines, for example the active matrix 3 has a number of connecting lines with chips 9 to the electronics printed circuit board 5.

Stabilization webs 8 made from a stable material insusceptible to breakage are fitted between the electronics printed circuit board 5 and the housing 17 in order to support the electronics printed circuit board 5, which is very susceptible to breakage, against impacts and further mechanical loads. Nevertheless, breakage of supply leads and electronic components located on the electronics printed circuit board 5 can very easily come about in the event of very slight bending of the electronics printed circuit board 5 owing to impact or shock loads.

FIG. 2 shows a flat image detector 1 according to an embodiment of the invention that has, for the purpose of better mechanical stabilization, an electronics printed circuit board that is subdivided into a number of individual printed circuit board modules 11. The printed circuit board modules 11 are interconnected by flexible electric connections 12. In addition, further stabilization webs 8 are fitted between the printed circuit board modules 11 and the housing 17 or between the substrate 4 and the housing 17.

The individual base surfaces of the printed circuit board modules 11 are respectively substantially smaller than the base surface of the flat image detector 1 according to an embodiment of the invention. Here, substantially smaller is to be understood in the sense that the individual printed circuit board modules have a base surface of at most 60% of the base surface of the overall electronics printed circuit board. As a result, in the event of the flat image detector 1 according to an embodiment of the invention being affected by impacts and shocks, the bending radii of the individual electronics printed circuit board modules 11 accompanying the deformation thereof are substantially smaller than the bending radius of an individual electronics printed circuit board 5 that is larger in terms of area; breaks in the supply leads thus come about significantly less frequently.

FIG. 3 shows a plan view of a section through a further flat image detector 20 according to an embodiment of the invention. The further flat image detector 20 according to an embodiment of the invention has a multiplicity of printed circuit board modules 11 that are arranged next to one another, for example. It is advantageous to form a first printed circuit board module 13 from an analog electronics unit, a second printed circuit board module 14 from a digital electronics unit, and a third printed circuit board module 15 from a communications electronics unit. Further printed circuit board modules 11, for example a fourth printed circuit board module 16, can take over further functions, for example controlling and regulating a power supply or an image processing system.

Alongside distinguishing specific functions in the printed circuit board modules 11, an arbitrary subdivision into individual printed circuit board modules 11 is also possible. The printed circuit board modules 11 can be arranged next to one another in the direction of the x-radiation—as shown in FIG. 2 and FIG. 3—or one below another.

At least one embodiment of the invention may be summarized briefly as follows: In order to ensure a mechanical stability against impact and bending that is as high as possible, it is provided in the case of a flat image detector for recording digital x-ray images and having a converter layer, an active pixel matrix made from pixel readout units and an electronics printed circuit board that the electronics printed circuit board is subdivided into at least two printed circuit board modules, and that the respective base surface of the printed circuit board modules is substantially smaller than the base surface of the electronics printed circuit board.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A flat image detector for recording digital x-ray images, comprising:
a converter layer; and
an active pixel matrix made from pixel readout units and an electronics printed circuit board with electronic components for controlling and regulating components of the flat image detector, the electronics printed circuit board being subdivided into at least two printed circuit board modules whose respective base surface is substantially smaller than the base surface of the electronics printed circuit board.

2. The flat image detector as claimed in claim 1, wherein at least two printed circuit board modules are interconnected via flexible lines.

3. The flat image detector as claimed in claim 1, wherein the flat image detector is designed as a mobile flat image detector.

4. The flat image detector as claimed in claim 1, wherein the printed circuit board modules are assigned various specific functions.

5. The flat image detector as claimed in claim 4, wherein a first printed circuit board module forms an analog electronics unit.

6. The flat image detector as claimed in claim 4, wherein a second printed circuit board module forms a digital electronics unit.

7. The flat image detector as claimed in claim 4, wherein a further printed circuit board module forms a communications electronics unit.

8. The flat image detector as claimed in claim 4, wherein a further printed circuit board module forms a drive and readout electronics unit.

9. The flat image detector as claimed in claim 1, wherein the flat image detector is designed as a mobile, wireless flat image detector.

10. The flat image detector as claimed in claim 5, wherein a second printed circuit board module forms a digital electronics unit.

11. The flat image detector as claimed in claim 10, wherein a further printed circuit board module forms a communications electronics unit.

12. The flat image detector as claimed in claim 11, wherein a further printed circuit board module forms a drive and readout electronics unit.

13. The flat image detector as claimed in claim 10, wherein a further printed circuit board module forms a drive and readout electronics unit.
